(19) United States
(12) Patent Application Publication
(10) Pub. No.: US 2013/0288411 A1
(43) Pub. Date: Oct. 31, 2013

(54) MANUFACTURING DEVICE AND METHOD OF LIQUID CRYSTAL PANEL

(71) Applicant: Shaoxin Yu, Shenzhen (CN)

(72) Inventor: Shaoxin Yu, Shenzhen (CN)

(21) Appl. No.: 13/634,317

(22) PCT Filed: May 14, 2012
(86) PCT No.: PCT/CN2012/075425

§ 371 Date: Sep. 12, 2012

(30) Foreign Application Priority Data
Apr. 26, 2012 (CN) 201210125060.7

(51) Int. Cl. H01J 9/24; H01L 33/08

(52) U.S. Cl. 438/30; 445/66; 257/E33.053

(57) ABSTRACT

A manufacturing device of a liquid crystal panel includes a lower fixing plate, an upper fixing plate located in a standby position and being separated from the lower fixing plate, or located in a bonding position and being bonded to the lower fixing plate, and at least one ultraviolet light source disposed around the lower fixing plate and located above the lower fixing plate. The sealant is pre-cured after the TFT substrate and the CF substrate are bonded and before the liquid crystal panel is transferred to the next manufacturing device, which improves the corrosion resistance of the sealant to liquid crystals and air, and also reduces or even eliminates the influence to the sealant caused by the corrosion in the following manufacturing process of the sealant. Thus, damage to the liquid crystal panel can be prevented even the transferring device breakdowns when the liquid crystal panel is transferred.

### BACKGROUND

1. Technical Field

The present disclosure relates to manufacturing technologies of liquid crystal panels and, particularly, to a manufacturing device and a manufacturing method of a liquid crystal panel.

2. Description of Related Art

Generally, a liquid crystal display (LCD) includes a thin film transistor (TFT) array substrate, a color filter (CF) substrate opposite to the TFT substrate, and a liquid crystal layer sandwiched between the TFT array substrate and the CF substrate. In a bonding process, sealant is coated on one of the two substrates, and liquid crystals are dropped on the other substrate. A vacuum bonding machine aligns the two substrates with each other and bonds the two substrates together in a vacuum state. The sealant bonds the TFT substrate and the CF substrate to prevent air from entering the liquid crystal layer.

However, after the two substrates are bonded together, the liquid crystals may spread and contact with the sealant. Since the sealant is uncured, the sealant may be dissolved after contacting the liquid crystals. Moreover, in the process of transferring the liquid crystal panel to a sealant curing device, the uncured sealant is exposed to air, which causes corrosion on the sealant. Referring to FIG. 1, the sealant being corroded by air and the liquid crystals in related art is schematically shown. Some parts of the sealant 30 contacting with the liquid crystals are corroded to define liquid crystal corroded regions 101, and the other parts of the sealant 30 exposed to air are corroded to define air corroded regions 201. If the sealant 30 cannot be cured in a predetermined time period, the sealant 30 may further be corroded to an extend in which each of the liquid crystal corroded regions 101 communicates with the corresponding air corroded region 201 to define a through hole, which allows air to enter the liquid crystal layer and thus result in the occurrence of air bubbles in the liquid crystal layer. This may damage the liquid crystal panel.

Generally, an ultraviolet (UV) light curing process or a thermal curing process is performed to cure the sealant. The sealant is sensitive to ultraviolet light. As shown in FIG. 2, the relationship between a cured degree of the sealant and the accumulated amount of ultraviolet light radiating on the sealant is schematically illustrated. When the accumulated amount of ultraviolet light radiating on the sealant reaches 200 mJ/cm², the sealant can be cured to be almost 90% of the completely cured state. Therefore, the UV light curing process is the common way to cure the sealant.

However, the vacuum bonding machine is independent from a UV light curing machine for performing the UV light curing process. The TFT substrate and the CF substrate are at first bonded together in the vacuum bonding machine. After that, the TFT substrate and CF substrate are transferred to the UV light curing machine to be exposed to ultraviolet light. During the process of transferring the TFT substrate and CF substrate to the UV light curing machine from the vacuum bonding machine, the uncured sealant is exposed to air, which causes corrosion to the sealant from the liquid crystal and air. Additionally, since it requires certain amount of time to transfer the TFT substrate and the CF substrate from the vacuum bonding machine to the UV light curing machine, the corrosion of the sealant may cause formation of through holes in the sealant. This may allow air to enter the liquid crystal thus damage the liquid crystal panel.

### SUMMARY

One object of the present disclosure is to provide a manufacturing device of a liquid crystal panel. The manufacturing device includes a lower fixing plate, an upper fixing plate movable between a standby position to be separated from the lower fixing plate and a bonding position to be bonded to the lower fixing plate, and at least one ultraviolet light source disposed around the lower fixing plate and located between the standby position and the lower fixing plate.

Preferably, the manufacturing device includes four of the ultraviolet light sources respectively corresponding to four edges of the lower fixing plate, and each of the ultraviolet light sources is substantially elongated.

Preferably, each of the ultraviolet light sources includes an ultraviolet light and a switch for turning on and off the ultraviolet light; and the manufacturing device further includes a control unit connected to the switch for controlling on and off of the switch.

Preferably, each of the ultraviolet light sources further includes a photo mask located on one side of the ultraviolet light.

Preferably, the control unit is further used for controlling the upper fixing plate to move to the bonding position from the standby position, or to move to the standby position from the bonding position.

Preferably, the manufacturing device further includes a positioning unit for positioning two substrates respectively located on the upper fixing plate and the lower fixing plate, and for aligning the two substrates with each other.

Preferably, the accumulated amount of light emitted from the at least one ultraviolet light source reaches 200 mJ/cm², and the illuminance of the light emitted therefrom reaches 100 mW/cm².

Another object of the present disclosure is to provide another manufacturing device a liquid crystal panel. The manufacturing device includes a lower fixing plate, an upper fixing plate located in a standby position and being separated from the lower fixing plate, or located in a bonding position and being bonded to the lower fixing plate, and at least one ultraviolet light source disposed around the lower fixing plate and located above the lower fixing plate.

Preferably, the at least one ultraviolet light source is disposed between the standby position and the lower fixing plate.

Preferably, each of the at least one ultraviolet light source includes an ultraviolet light and a switch for turning on and off the ultraviolet light; and the manufacturing device further includes a control unit connected to the switch for controlling on and off of the switch.

Preferably, the control unit is further used for controlling the upper fixing plate to move to the bonding position from the standby position, or to move to the standby position from the bonding position.

Preferably, the manufacturing device further includes a positioning unit for positioning two substrates respectively placed on the upper fixing plate and the lower fixing plate, and for aligning the two substrates with each other.

Preferably, the accumulated amount of light emitted from the at least one ultraviolet light source reaches 200 mJ/cm², and the illuminance of the light emitted therefrom reaches 100 mW/cm².

Yet another object of the present disclosure is to provide a manufacturing method of a liquid crystal panel. The manufacturing method includes the following steps: step S1: moving an upper fixing plate from the a standby position to a bonding position to bond a thin film transistor substrate and a color filter substrate of the liquid crystal panel, and turning off at least one ultraviolet light source; and step S2: moving the upper fixing plate from the bonding position to the standby position, and simultaneously turning on the at least one ultraviolet light source to allow light emitted therefrom to radiate on the liquid crystal panel with the thin film transistor substrate and the color filter substrate being bonded.

Preferably, the step S2 can also be: moving the upper fixing plate from the bonding position to the standby position, and turning on at least one ultraviolet light source after the upper fixing plate is located in the standby position to allow light emitted therefrom to radiate on the liquid crystal panel with the thin film transistor substrate and the color filter substrate being bonded.

Preferably, the accumulated amount of light emitted from the at least one ultraviolet light source reaches 200 mJ/cm², and the illuminance of the light emitted therefrom reaches 100 mW/cm².

Preferably, the step S2 further includes: transferring the liquid crystal panel after the thin film transistor substrate and the color filter substrate are bonded.

Preferably, the step S1 includes: placing the thin film transistor substrate and the color filter substrate on two predetermined positions of the upper fixing plate and the lower fixing plate respectively, positioning the thin film transistor substrate and the color filter substrate, moving the upper fixing plate towards the bonding position from the standby position to bond the thin film transistor substrate and the color filter substrate, and turning off the at least one ultraviolet light source.

In manufacturing device and method of the liquid crystal panel of the present disclosure, the sealant is pre-cured after the TFT substrate and the CF substrate are bonded and before the liquid crystal panel with the two substrates being bonded is transferred to the next manufacturing device, which improves the corrosion resistance of the sealant to liquid crystals and air, and may also reduce or even eliminate the influence to the sealant caused by the corrosion in the following manufacturing process of the sealant. Thus, the liquid crystal panel can be prevented from being damaged even the transferring device breakdowns in the process of transferring the liquid crystal panel.

### DESCRIPTION OF THE DRAWINGS

Many aspects of the embodiments can be better understood with reference to the following drawings. The components in the drawings are not necessarily dawns to scale, the emphasis instead being placed upon clearly illustrating the principles of the embodiments. Moreover, in the drawings, like reference numerals designate corresponding parts throughout the several views.

FIG. 1 is a schematic view showing corrosion of a sealant due to liquid crystals and air in related art;

FIG. 2 is a schematic view showing the relationship between the sealant cured degree of the sealant of a LCD and the accumulated amount of ultraviolet light radiating on the sealant;

FIG. 3 is a schematic view of a manufacturing device of a liquid crystal panel in accordance with a first embodiment of the present disclosure;

FIG. 4 is a schematic view of placing a TFT substrate and a CF substrate in the manufacturing device of FIG. 3, and the manufacturing device includes an upper fixing plate located in a standby position;

FIG. 5 is a schematic view showing the state of the manufacturing device of FIG. 3 after the TFT substrate and the CF substrate are bonded together;

FIG. 6 is a schematic view showing that the manufacturing device of FIG. 3 pre-cures the sealant;

FIG. 7 is a flow chart of a manufacturing method of a liquid crystal panel in accordance with an embodiment of the present disclosure.

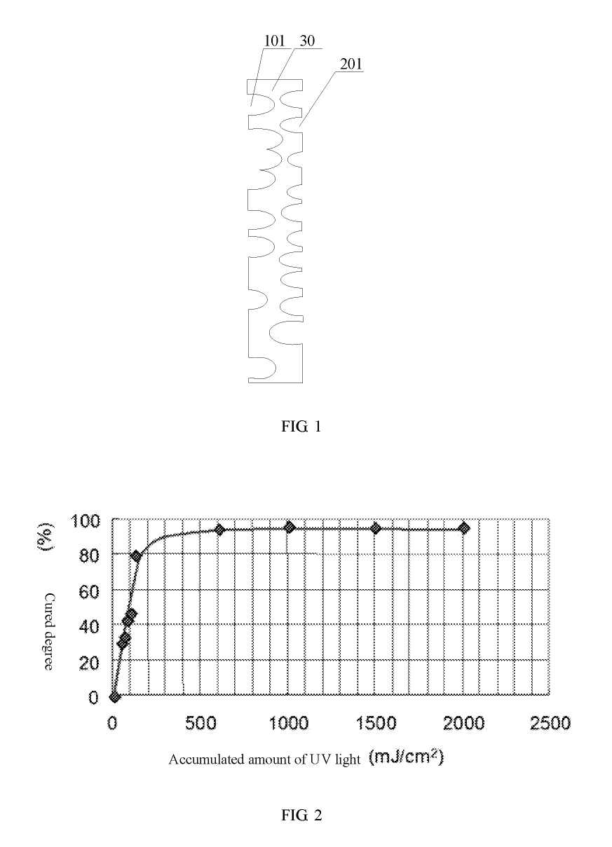

### DETAILED DESCRIPTION

The disclosure is illustrated by way of example and not by way of limitation in the figures of the accompanying drawings in which like references indicate similar elements. It should be noted that references to “an” or “one” embodiment is this disclosure are not necessarily to the same embodiment, and such references mean at least one.

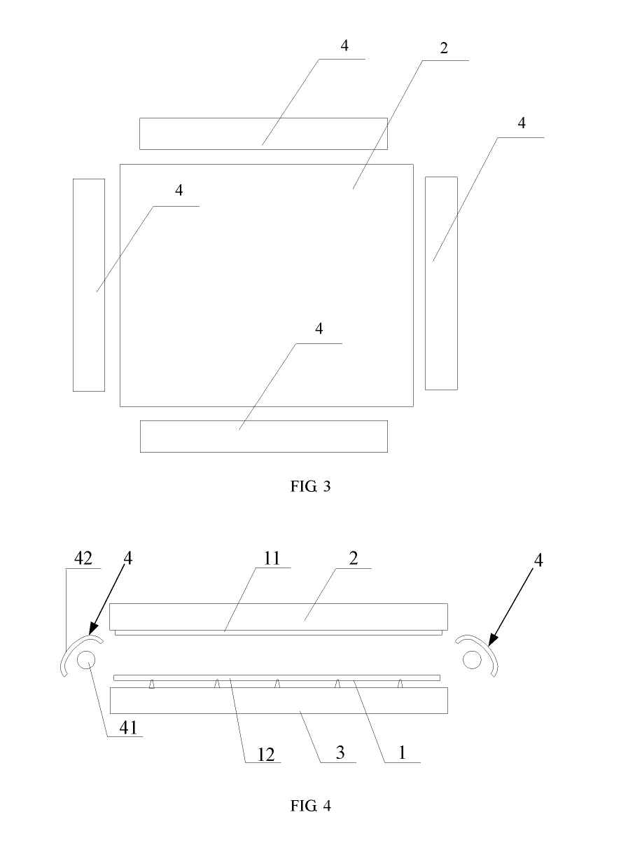

Referring to FIGS. 3 to 5, FIG. 3 is a schematic view of a manufacturing device of a liquid crystal panel in accordance with a first embodiment of the present disclosure, FIG. 4 is a schematic view of placing a TFT substrate and a CF substrate in the manufacturing device, and the manufacturing device includes an upper fixing plate located in a standby position, and FIG. 5 is a schematic view showing the state of the manufacturing device after the TFT substrate and the CF substrate are bonded together. The liquid crystal panel includes a thin film transistor (TFT) substrate 11, a color filter (CF) substrate 12, and sealant (not shown) for bonding the TFT substrate 11 and the CF substrate 12. A number of ultraviolet (UV) light sources 4 are disposed in the manufacturing device of the liquid crystal panel for pre-radiating the sealant of the liquid crystal panel 1.

The manufacturing device includes an upper fixing plate 2, a lower fixing plate 3 opposite to the upper fixing plate 2, and a controlling unit (not shown). The upper fixing plate 2, the lower fixing plate 3, and the controlling unit cooperate with each other to bond the TFT substrate 11 and the CF substrate 12. The upper fixing plate 2 is movable between a standby position and a bonding position. The standby position in the embodiment is referred to a position in which the upper fixing plate 2 is highest located above the lower fixing plate 3, namely the position in which the upper fixing plate 2 is kept still and ready to move downwards. The bonding position is referred to a position in which the upper fixing plate 2 is located when the upper fixing plate 2 and the lower fixing plate 3 cooperates with the upper plate 2 to bond the TFT substrate 11 and the CF substrate 12. The upper fixing plate 2 is used for supporting the TFT substrate 11, and the lower fixing plate 3 is used for supporting the CF substrate 12. The lower fixing plate 3 is further used for supporting the TFT substrate 11 and the CF substrate 2 after the TFT substrate 11 is bonded to the CF substrate 2. It is noted that in other embodiments, the upper fixing plate 2 may be used for supporting the CF substrate 12, and the lower fixing plate 3 may be correspondingly used for supporting the TFT substrate 11. The controlling unit is configured for controlling the upper fixing plate 2 to move to the bonding position from the standby position or to move the standby position from the bonding position.

The liquid crystal panel further includes a positioning unit (not shown) for positioning the substrates respectively placed on the upper fixing plate 2 and the lower fixing plate 3 such that the two substrates can be aligned with each other.

The UV light sources 4 are located around the upper fixing plate 2 and the lower fixing plate 3, and are located above the lower fixing plate 3. Each of the UV light sources 4 can be stripped or can be configured in other shapes. The manufacturing device may include four of the UV light sources 4 located around the lower fixing plate 3, or may include two or more than four of the UV light sources.

In the embodiment, the manufacturing device includes four of the UV light sources 4 respectively corresponding to four edges of the lower fixing plate 3. The UV light sources 4 are disposed between the standby position of the upper fixing plate 2 and the lower fixing plate 3, and are located outside the upper and lower fixing plates 2, 3. That is, the UV light sources 4 are located above the lower fixing plate 3 for radiating on the sealant in a top-to-bottom way and thus pre-curing the sealant.

Each of the UV light sources 4 includes a UV light 41, a photo mask 42, and a switch (not shown). The photo mask 42 is disposed on one side of the UV light 41 for reflecting the light emitted from the UV light 41 to the lower fixing plate 3. The switch is used for turning on and off of the UV light 41. The switch is connected to the control unit and is controlled by the control unit to turn on and off the UV light 41.

The process of pre-curing the sealant via the UV light sources 4 of the manufacturing device is described in the following.

Before the liquid crystal panel is transferred to the manufacturing device, liquid crystals are dropped on one of the TFT substrate 11 and the CF substrate 12, and the sealant is correspondingly coated on the other one of the two substrates 11, 12. In the embodiment, the liquid crystals are dropped on the TFT substrate 11 and the sealant is coated on the CF substrate 12.

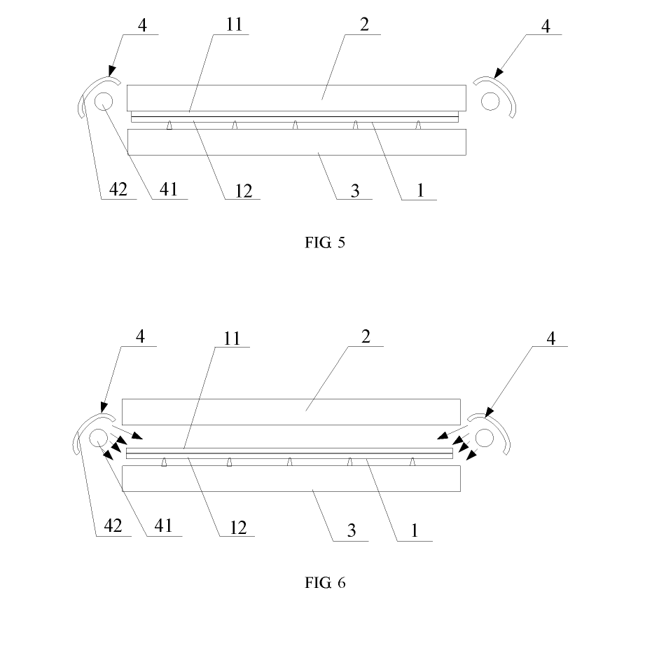

A transferring device (not shown) transfers the TFT substrate 11 with the liquid crystal dropped thereon and the CF substrate 12 with the sealant coated thereon to two predetermined positions on the upper fixing plate 2 and the lower fixing plate 3 respectively such that the TFT substrate 11 and the CF substrate 12 can be positioned by the positioning unit. Thus, the TFT substrate 11 can be aligned with the CF substrate 12. As shown in FIG. 4, at this time, the upper fixing plate 2 is located in the standby position. The control unit controls the upper fixing plate 2 to move to the bonding position from the standby position to bond the TFT substrate 11 and the CF substrate 12. Each of the UV lights 41 is in off state during the process. As shown in FIG. 5, the TFT substrate 11 and the CF substrate 12 are bonded. After the TFT substrate 11 and the CF substrate 12 are bonded, the upper fixing plate 2 is moved upwards to the standby position from the bonding position, as shown in FIG. 6. While the upper fixing plate 2 is being moved to the standby position from the bonding position, the control unit controls the switch to turn on the UV lights 41. The light emitted from the UV lights 41 (as the arrows shown in FIG. 6) radiates on the sealant to pre-cure the sealant. It is noted that in other embodiments, the UV lights 41 can be turned on after the upper fixing plate 2 is located in the standby position.

In the embodiment, the accumulated amount of ultraviolet light emitted from the UV lights 41 can reach 200 mJ/cm², and the illuminance of the ultraviolet light can reach 100 mW/cm², which is capable of pre-curing the sealant to be 90% the completely cured state in two seconds. Since the time for pre-curing the sealant is short, the pre-curing process of the sealant can be finished before the liquid crystal panel 1 is transferred out of the manufacturing device by the transferring device. That is, the pre-curing process of the sealant is simultaneously carried out while the transferring device is transferring the liquid crystal panel 1 with the two substrates 11, 12 being bonded together. This prevents the manufacturing process of the liquid crystal panel from being influenced.

The UV lights 41 of the manufacturing device of the present disclosure can pre-cure the sealant before the liquid crystal panel with the two substrates being bonded is transferred to the next manufacturing device, which improves the corrosion resistance of the sealant to liquid crystals and air, and may also reduce or even eliminate the influence to the sealant caused by the corrosion in the following manufacturing process of the sealant. Thus, the liquid crystal panel 1 can be prevented from being damaged even if the transferring device breakdowns in the process of transferring the liquid crystal panel.

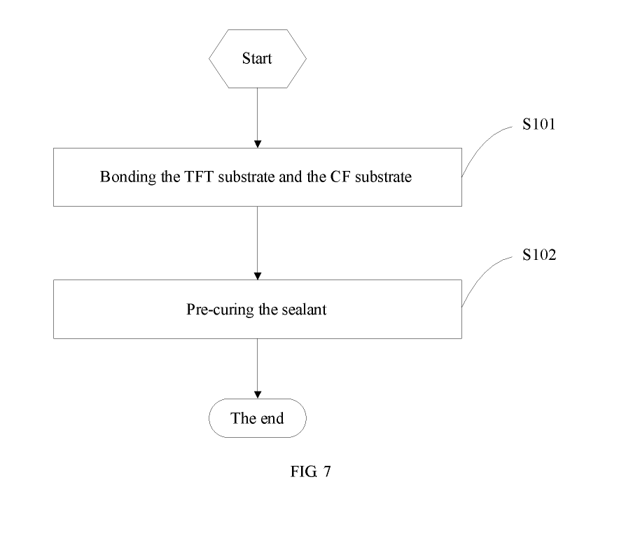

Referring to FIG. 7, a manufacturing method of the liquid crystal panel is provided. The manufacturing method includes the following steps:

Step S101, bonding the TFT substrate and the CF substrate. Referring also to FIGS. 4 and 5, liquid crystal is dropped on one of the TFT substrate 11 and the CF substrate 12, and the sealant is correspondingly coated on the other one of the two substrates 11, 12. In the embodiment, the liquid crystals are dropped on the TFT substrate 11 and the sealant is coated on the CF substrate 12.

A transferring device (not shown) transfers the TFT substrate 11 with the liquid crystal dropped thereon and the CF substrate 12 with the sealant coated thereon to two predetermined positions on the upper fixing plate 2 and the lower fixing plate 3 respectively such that the TFT substrate 11 and the CF substrate 12 can be positioned by the positioning unit. Thus, the TFT substrate 11 can be aligned with the CF substrate 12. As shown in FIG. 4, at this time, the upper fixing plate 2 is located in the standby position. The control unit controls the upper fixing plate 2 to move to the bonding position from the standby position to bond the TFT substrate 11 and the CF substrate 12. Each of the UV lights 41 is in off state during the process. As shown in FIG. 5, the TFT substrate 11 and the CF substrate 12 are bonded.

Step S102, pre-curing the sealant. Referring to FIG. 6, after the TFT substrate 11 and the CF substrate 12 are bonded, the upper fixing plate 2 is moved upwards to the standby position from the bonding position, as shown in FIG. 6. While the upper fixing plate 2 is being moved to the standby position from the bonding position, the control unit controls the switch to turn on the UV lights 41. The ultraviolet light emitted from the UV lights 41 (as the arrows shown in FIG. 6) radiates on the sealant to pre-cure the sealant. It is noted that in other embodiments, the UV lights 41 can be turned on after the upper fixing plate 2 is located in the standby position.

In the embodiment, the accumulated amount of ultraviolet light emitted from the UV lights 41 can reach 200 mJ/cm², and the illuminance of the ultraviolet light can reach 100 mW/cm², thus, the sealant can be pre-cured to be 90% the completely cured state in two seconds. Since the time for pre-curing the sealant is short, the pre-curing process of the sealant can be finished before the liquid crystal panel 1 is transferred out of the manufacturing device by the transferring device. That is, the pre-curing process of the sealant is simultaneously carried out while the transferring device is transferring the liquid crystal panel with the two substrates 11, 12 being bonded together, which prevents the manufacturing process of the liquid crystal panel 1 from being influenced.

The UV lights 41 of the manufacturing device of the present disclosure can pre-cure the sealant before the liquid crystal panel with the two substrates being bonded together is transferred to the next manufacturing device, which improves the corrosion resistance of the sealant to liquid crystals and air, and may also reduce or even eliminate the influence to the sealant caused by the corrosion in the following manufacturing process of the sealant. Thus, the liquid crystal panel 1 can be prevented from being damaged even the transferring device breakdowns in the process of transferring the liquid crystal panel 1.

After the sealant is pre-cured, the liquid crystal panel is transferred to the UV light curing device for further being cured to reach the completely cured state.

The UV lights 41 of the manufacturing device and the manufacturing method of the present disclosure can pre-cure the sealant before the liquid crystal panel with the two substrates being bonded is transferred to the next manufacturing device, which improves the corrosion resistance of the sealant to liquid crystal and air, and may also reduce or even eliminate the influence to the sealant caused by the corrosion in the following manufacturing process of the sealant. Thus, the liquid crystal panel 1 can be prevented from being damaged even the transferring device breakdowns in the process of transferring the liquid crystal panel.

Even though information and the advantages of the present embodiments have been set forth in the foregoing description, together with details of the mechanisms and functions of the present embodiments, the disclosure is illustrative only; and that changes may be made in detail, especially in matters of shape, size, and arrangement of parts within the principles of the present embodiments to the full extend indicated by the broad general meaning of the terms in which the appended claims are expressed.

What is claimed is:

1. A manufacturing device of a liquid crystal panel, comprising:
a lower fixing plate;
an upper fixing plate movable between a standby position to be separated from the lower fixing plate and a bonding position to be bonded to the lower fixing plate; and
at least one ultraviolet light source disposed around the lower fixing plate and located between the standby position and the lower fixing plate.

2. The manufacturing device as claimed in claim 1, wherein the manufacturing device comprises four of the ultraviolet light sources respectively corresponding to four edges of the lower fixing plate, and each of the ultraviolet light sources is substantially elongated.

3. The manufacturing device as claimed in claim 2, wherein each of the ultraviolet light sources comprises an ultraviolet light and a switch for turning on and off the ultraviolet light; and the manufacturing device further comprises a control unit connected to the switch for controlling on and off of the switch.

4. The manufacturing device as claimed in claim 3, wherein each of the ultraviolet light sources further comprises a photo mask located on one side of the ultraviolet light.

5. The manufacturing device as claimed in claim 3, wherein the control unit is further used for controlling the upper fixing plate to move to the bonding position from the standby position, or to move to the standby position from the bonding position.

6. The manufacturing device as claimed in claim 1 further comprising a positioning unit for positioning two substrates respectively located on the upper fixing plate and the lower fixing plate, and for aligning the two substrates with each other.

7. The manufacturing device as claimed in claim 1, wherein the accumulated amount of light emitted from the at least one ultraviolet light source reaches 200 mJ/cm², and the illuminance of the light emitted therefrom reaches 100 mW/cm².

8. A manufacturing device of a liquid crystal panel, comprising:
a lower fixing plate;
an upper fixing plate located in a standby position and being separated from the lower fixing plate, or located in a bonding position and being bonded to the lower fixing plate; and
at least one ultraviolet light source disposed around the lower fixing plate and located above the lower fixing plate.

9. The manufacturing device as claimed in claim 8, wherein the at least one ultraviolet light source is disposed between the standby position and the lower fixing plate.

10. The manufacturing device as claimed in claim 9, wherein each of the at least one ultraviolet light source comprises an ultraviolet light and a switch for turning on and off the ultraviolet light; and the manufacturing device further comprises a control unit connected to the switch for controlling on and off of the switch.

11. The manufacturing device as claimed in claim 10, wherein the control unit is further used for controlling the upper fixing plate to move to the bonding position from the standby position, or to move to the standby position from the bonding position.

12. The manufacturing device as claimed in claim 8 further comprising a positioning unit for positioning two substrates respectively placed on the upper fixing plate and the lower fixing plate, and for aligning the two substrates with each other.

13. The manufacturing device as claimed in claim 8, wherein the accumulated amount of light emitted from the at least one ultraviolet light source reaches 200 mJ/cm², and the illuminance of the light emitted therefrom reaches 100 mW/cm².

14. A manufacturing method of a liquid crystal panel, comprising:
step S1: moving an upper fixing plate from the a standby position to a bonding position to bond a thin film transistor substrate and a color filter substrate of the liquid crystal panel, and turning off at least one ultraviolet light source; and
step S2: moving the upper fixing plate from the bonding position to the standby position, and simultaneously turning on the at least one ultraviolet light source to allow light emitted therefrom to radiate on the liquid crystal panel with the thin film transistor substrate and the color filter substrate being bonded.

15. The manufacturing method as claimed in claim 14, wherein the step S2 can also be: moving the upper fixing plate from the bonding position to the standby position, and turning on at least one ultraviolet light source after the upper fixing plate is located in the standby position to allow light emitted therefrom to radiate on the liquid crystal panel with the thin film transistor substrate and the color filter substrate being bonded.

16. The manufacturing method as claimed in claim 14, wherein the accumulated amount of light emitted from the at least one ultraviolet light source reaches 200 mJ/cm², and the illuminance of the light emitted therefrom reaches 100 mW/cm².

17. The manufacturing method as claimed in claim 16, wherein the step S2 further comprises: transferring the liquid crystal panel after the thin film transistor substrate and the color filter substrate are bonded.

18. The manufacturing method as claimed in claim 14, wherein the step S1 comprises: placing the thin film transistor substrate and the color filter substrate on two predetermined positions of the upper fixing plate and the lower fixing plate respectively, positioning the thin film transistor substrate and the color filter substrate, moving the upper fixing plate towards the bonding position from the standby position to bond the thin film transistor substrate and the color filter substrate, and turning off the at least one ultraviolet light source.
